(19) United States
(12) Patent Application Publication
(10) Pub. No.: US 2014/0153166 A1
(43) Pub. Date: Jun. 5, 2014

(54) ELECTRONIC APPARATUS AND DETACHABLE ASSEMBLY THEREOF

(71) Applicant: Wistron Corporation, New Taipei City (TW)

(72) Inventors: ZHONG-HUI MAO, New Taipei City (TW); DONG-YING CHEN, New Taipei City (TW)

(73) Assignee: Wistron Corporation, New Taipei City (TW)

(21) Appl. No.: 14/041,346

(22) Filed: Sep. 30, 2013

(30) Foreign Application Priority Data
Nov. 30, 2012 (CN) 201210506276.8

(51) Int. Cl. H05K 5/02

(52) U.S. Cl. CPC H05K 5/02; H05K 5/0221
USPC 361/679.01; 312/223.2

(57) ABSTRACT

A detachable assembly for an electronic apparatus includes a main frame, a tray and at least one button unit. The tray for mounting a storage device is combined detachably with the main frame and includes two lateral boards. Each lateral board extends outward to form an actuation part included a hook part. Each button unit includes a button combined movably with the main frame, and the button includes a protruding part corresponding to the hook part. When the tray is combined with the main body, the tray is locked by the protruding part fixing each hook part. When each button is forced to move toward the main frame along an axis, each protruding part is released from each hook part, and the tray is pushed by each button to move along a plane substantially perpendicular to the axis. Then the tray is detached from the main frame.

### BACKGROUND OF THE DISCLOSURE

1. Field of Disclosure

The present disclosure relates to a detachable assembly of an electronic apparatus, and more particularly, it relates to a detachable assembly of an electronic apparatus for assembling and detaching a storage device easily.

2. Background

For electronic apparatuses like computers or network storage devices, one or more storage devices (like hard disks or optical disks) can be disposed therein for data access. The storage devices usually are fixed in the housing of the electronic apparatus by a plurality of bolts. When a user wants to replace an original storage device for a new storage device, he or she needs to remove all the bolts with tools before taking the original storage devices out; similarly, the plurality of bolts need to be fastened with tools while installing the new storage device. It is very inconvenient for the user.

Some assistance devices (like removable hard disk enclosures) are used for assembling/detaching storage devices easily. However, the removable hard disk enclosures still have problems with assembly similar to those mentioned above. In addition, the removable hard disk enclosures cannot be applied to every type of computer or network storage device.

Therefore, it is beneficial to design a detachable assembly for the electronic apparatus to assemble or detach a storage device without any tools so as to avoid the inconvenience of repeatedly fastening or unfastening bolts.

### SUMMARY OF THE DISCLOSURE

A major objective of the present disclosure is to provide a detachable assembly of an electronic apparatus for assembling/detaching a storage device.

To achieve the aforementioned objective, a detachable assembly of an electronic apparatus includes a main frame, a tray and at least one button unit. The tray is used for mounting a storage device and is detachably combined with the main frame. The tray includes two lateral boards opposite to each other. Each lateral board extends outwardly to form an actuation part. The actuation part includes a hook. Each button unit includes a button movably combined with the main frame, and the button includes a protruding part corresponding to the hook.

When the tray is combined with the main frame and located in a fixed position, the protruding part of each button and each hook of the tray form a locked status. When each button moves along an axis toward the main frame due to an external force, each protruding part releases from the locked status with each hook. The tray is pushed by the button to move along a plane substantially perpendicular to the axis such that the tray leaves the fixed position and is detached from the main frame.

The present disclosure further includes an embodiment of an electronic apparatus. The electronic apparatus includes a housing, a circuit board and the detachable assembly as mentioned above. The circuit board and the detachable assembly are disposed in the housing. By mounting and fixing the storage device with the detachable assembly, the storage device disposed in the electronic apparatus can be assembled or detached easily.

Accordingly, the storage device is fixed on the tray, and the tray is combined slidably with the main frame by the corresponding fastener structures. When the tray needs to be separated from the main frame, the user needs only to press each button to release the fixed status between the tray and the main frame to eject the tray, so the user can easily replace the storage device without using any tools.

### BRIEF DESCRIPTION OF THE DRAWINGS

FIG. 1 is an exploded diagram of an electronic apparatus according to the present disclosure;

FIG. 2 is a structural diagram of a main frame of a detachable assembly of the electronic apparatus according to the present disclosure;

FIG. 3 is a structural diagram of a tray of the detachable assembly of the electronic apparatus according to the present disclosure;

FIG. 4(a) is an exploded diagram of a button unit with a fixing support in the detachable assembly of the electronic apparatus according to the present disclosure;

FIG. 4(b) is a structural diagram of a button of the detachable assembly of the electronic apparatus viewed from another angle according to the present disclosure;

FIG. 4(c) is a structural diagram of the button unit combined with the fixing support in the detachable assembly in the electronic apparatus according to the present disclosure;

FIG. 5(a) illustrates a combination process of the tray and the main frame in the detachable assembly of the electronic apparatus according to the present disclosure;

FIG. 5(b) illustrates the status after the tray is combined with the main frame in the detachable assembly of the electronic apparatus according to the present disclosure;

FIG. 5(c) is a sectional diagram of the status after the tray is combined with the main frame in the detachable assembly of the electronic apparatus according to the present disclosure;

FIG. 6(a) illustrates a locked status of the button and the tray in the detachable assembly of the electronic apparatus;

FIG. 6(b) illustrates the release of the locked status of the button and the tray in the detachable assembly of the electronic apparatus after the button is pressed;

FIG. 7(a) illustrates a side view before the button pushes the tray in the detachable assembly of the electronic apparatus, and

FIG. 7(b) illustrates a side view after the button pushes the tray in the detachable assembly of the electronic apparatus.

### DETAILED DESCRIPTION OF THE PREFERRED EMBODIMENT

To better explain the technical contents of the present disclosure, the following embodiments are provided for explanation.

An electronic apparatus of the present disclosure can be applied in a computer device (e.g. a desktop computer, a server or a laptop computer), a network storage apparatus or other device that has a storage device. In one embodiment, the electronic apparatus of the present disclosure is illustrated with an example of a network storage apparatus, but it is not limited to this application.

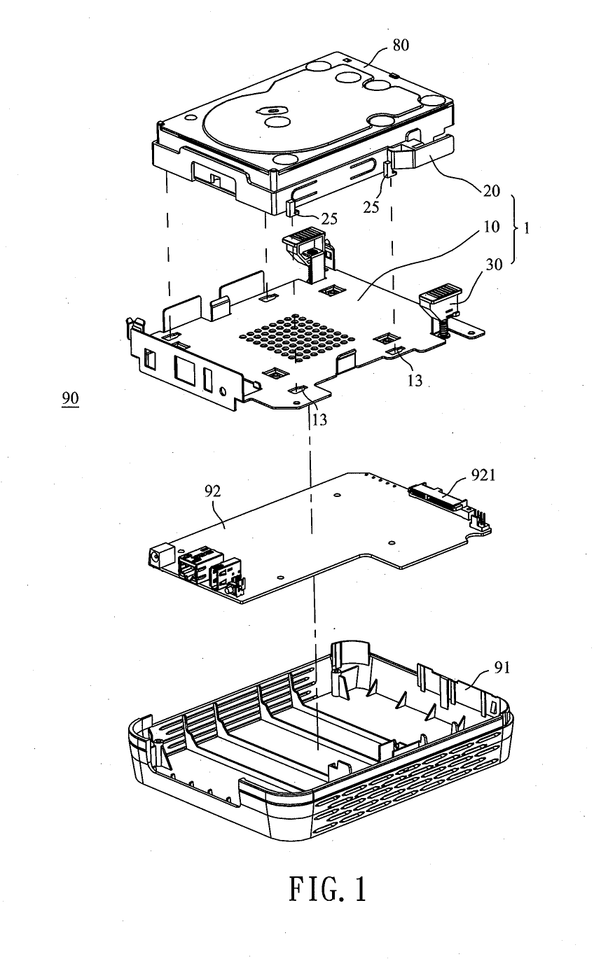

Please refer to FIG. 1, which is an exploded diagram of an electronic apparatus 90 of the present disclosure. It should be noted that a portion of a housing 91 (e.g. upper housing) of the electronic apparatus 90 is omitted for clearly showing the structure design of the present disclosure.

As shown in FIG. 1, the electronic apparatus 90 includes a housing 91, a circuit board 92, and a detachable assembly 1. The circuit board 92 and the detachable assembly 1 are both disposed in the housing 91. The detachable assembly 1 is used for mounting a storage device 80. The storage device 80 is electrically connected to the circuit board 92 by a connector 921 of the circuit board 92 for data transmission.

The detachable assembly 1 includes a main frame 10, a tray 20 and at least one button unit 30. The main frame 10 can be a basic frame of the electronic apparatus 90. The tray 20 is used for mounting and fixing the storage device 80, e.g. a hard disk or an optical drive, and the tray 20 is detachably combined with the main frame 10. At least one button unit 30 is combined with the main frame 10. By locking or linking functions formed between the each button unit 30 and the tray 20, the tray 20 can be fixed on the main frame 10 or released from a locked status with the main frame 10.

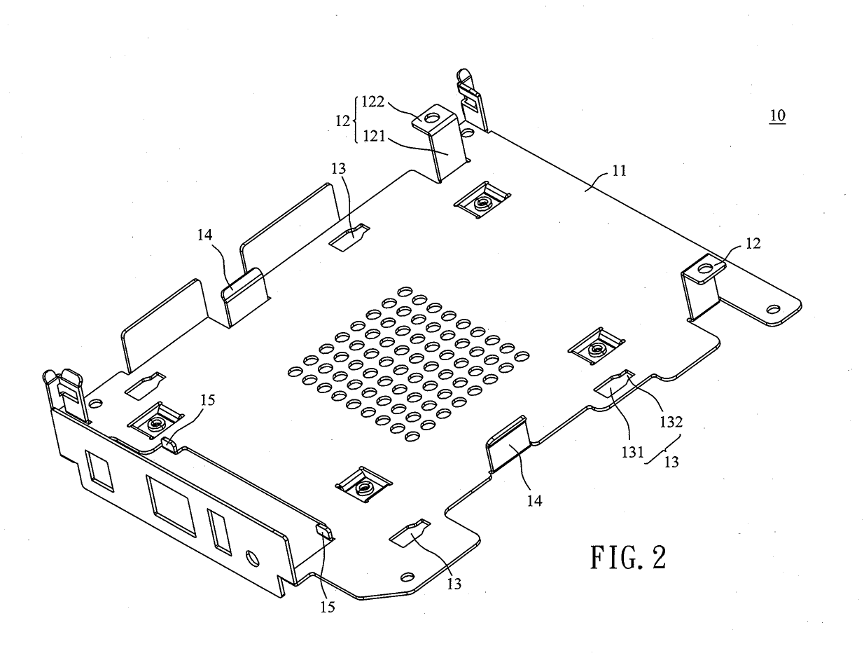

Please refer to FIG. 2, which is a structural diagram of a main frame 10 of the detachable assembly 1 of the electronic apparatus according to the present disclosure.

As shown in FIG. 1 and FIG. 2, the main frame 10 includes a main body 11 and at least one fixing support 12. Each fixing support 12 is used for combining each button unit 30. Each fixing support 12 includes an erect part 121 and a bending part 122 substantially perpendicular to the erect part 121. That is, the erect part 121 is substantially perpendicular to the main body 11, and the bending part 122 is substantially parallel to the main body 11. In this embodiment, two fixing supports 12 are disposed symmetrically on the main body 11 for providing even force actuation effect, but the present disclosure is not limited to this. One or more fixing supports 12 can be disposed for different design requirements.

The main frame 10 further includes a plurality of holes 13 disposed on the main body 11 for combining and fixing the tray 20 to the main frame 10 with associated structures (explained as follows) of the tray 20. Each hole 13 includes a through hole 131 and an extending hole 132 connecting to the through hole 131. A diameter of the through hole 131 is larger than a diameter of the extending hole 132. The shapes and sizes of the through hole 131 and the extending hole 132 can be changed for different design requirements; e.g., circular holes, rectangular holes or other forms. The plurality of holes 13 are disposed at positions corresponding to positions of associated structures of the tray 20. In one embodiment, the four holes 13 are diversely disposed at proper positions of each corner of the main body 11, but the present disclosure is not limited to this.

The main frame 10 further includes a plurality of guiding parts 14 disposed on the main body 11 to correspond to a sliding path of the tray 20. The plurality of guiding parts 14 guide the tray 20 to move on the main frame 10 such that each fastener 25 of the tray 20 can easily pass through each hole 13 of the main frame 10. In addition, the main frame 10 further includes at least one block part 15 for blocking the tray 20 to limit a moving distance when the tray 20 is ejected from the main frame 10.

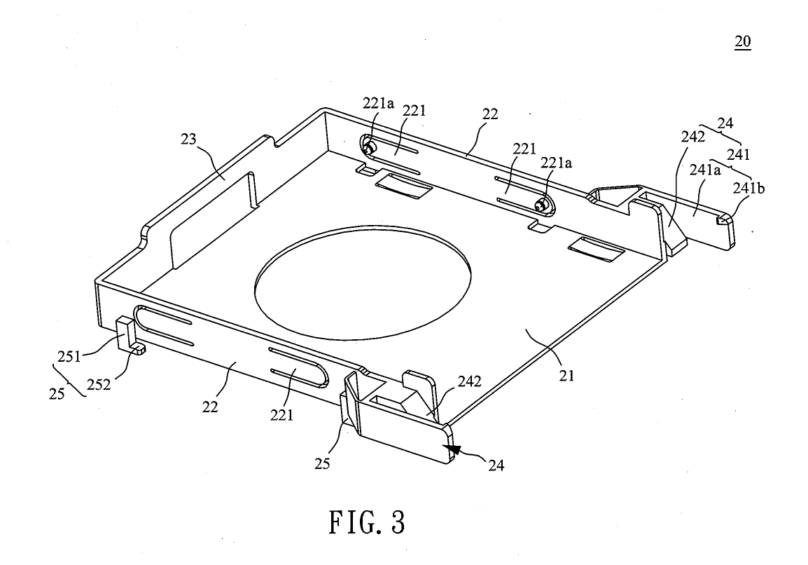

Please refer to FIG. 1 and FIG. 3. FIG. 3 is a structure diagram of the tray 20 of the detachable assembly 1 of the electronic apparatus according to the present disclosure.

As shown in FIG. 1 and FIG. 3, the tray 20 includes a base board 21, two lateral boards 22 disposed opposite to each other, and a back board 23. The back board 23 and each lateral board 22 are substantially perpendicularly connected to the base board 21. Two ends of the back board 23 are respectively substantially perpendicularly connected to the two lateral boards 22 and form a surrounding mounting area for mounting the storage device 80.

The base board 21 includes a plurality of buffer structures 211. Each buffer structure 211 protrudes from a surface of the base board 21 and contacts the main frame 10. Each buffer structure 211 is used for decreasing the contact area when the tray 20 is combined with the main frame 10 and providing a buffer effect between the tray 20 and the main frame 10. In one embodiment, the four buffer structures 211 are diversely disposed at proper positions of each corner of the base board 21. In this embodiment, each buffer structure is an elastic arch structure, but the present disclosure is not limited to this.

Each lateral board 22 includes at least one elastic piece 221, and each elastic piece 211 has a convex column 221a. Each convex column 221a is disposed at a position corresponding to a bolt hole (not shown) of the storage device 80 such that each convex column 221a can be inserted into each corresponding bolt hole to fix the storage device 80 when the storage device 80 is combined with the tray 20. The design of the elastic pieces 221 is also help to assemble or detach the storage device easily. In one embodiment, two elastic pieces 221 are disposed in each lateral board 22 for corresponding to two predetermined bolt holes of each lateral side of the storage device 80. The numbers and positions of the elastic pieces 221 can be changed according to different designs.

Each lateral board 22 extends outwardly in direction away from the base board 21 to form an actuation part 24 to avoid influencing the detachment of the storage device 80 or electrical contact of the storage device 80 with other components in the electronic apparatus. Each actuation part 24 includes a hook part 241 and a corresponding inclined plane 242. The corresponding inclined plane 242 is closer to the base board 21 than the hook part 241 is, and the corresponding inclined planes 242 are disposed corresponding to a corresponding structure (explained as follows) of the button units 30. The hook part 241 includes a spring arm 241a and a hook 241b. The hook 241b is located at one side of the spring arm 241a toward the base board 21 and is close to an upper position of the spring arm 241a. The hook 241b is used for performing actuation according to another corresponding structure (explained as follows) of the button unit 30 to fix the tray 20 to the main frame 10. An angle exists between the corresponding inclined plane 242 and the base board 21, and the angle is less than 45 degrees so as to generate sufficient driving force between the inclined planes.

As shown in FIG. 2 and FIG. 3, the tray 20 further includes a plurality of fastener parts 25 corresponding to the plurality of holes 13 of the main frame 10. The plurality of fastener parts 25 passes through the plurality of holes 13 when the tray 20 is combined with the main frame 10. When the tray 20 is moved to a fixed position with respect to the main frame 10, the tray 20 is fixed to the main frame 10 by the plurality of fastener parts 25. Each fastener part 25 includes a connecting part 251 and an extending part 252. One end of the connecting part 251 is connected to the base board 21 or to the lateral board 22, and the other end of the connecting part 251 is connected to the extending part 252. The extending part 252 is extended from the connecting part 251 and substantially parallel to the base board 21. A distance is kept between the extending part 252 and the base board 21 for fixing the main frame 10. A position of each fastener part 25 is disposed corresponding to a position of each hole 13 of the main frame 10. According to design, the through hole 131 of each through hole 13 allows the whole of each fastener part 25 to pass through it. That is, the through hole 131 allows both the connecting part 251 and the extending part 252 of the fastener part 25 to pass through it. The extending hole 132 of each through hole 13 allows only the connecting part 251 of the fastener part 25 to pass through it.

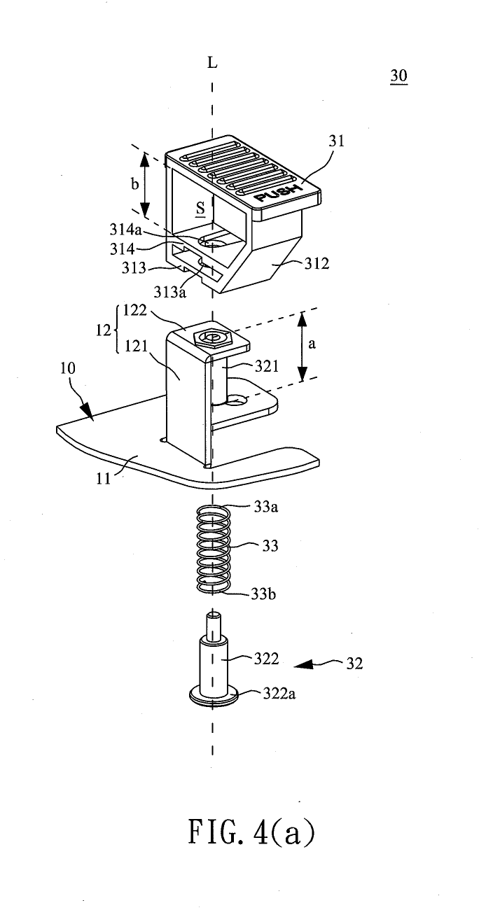

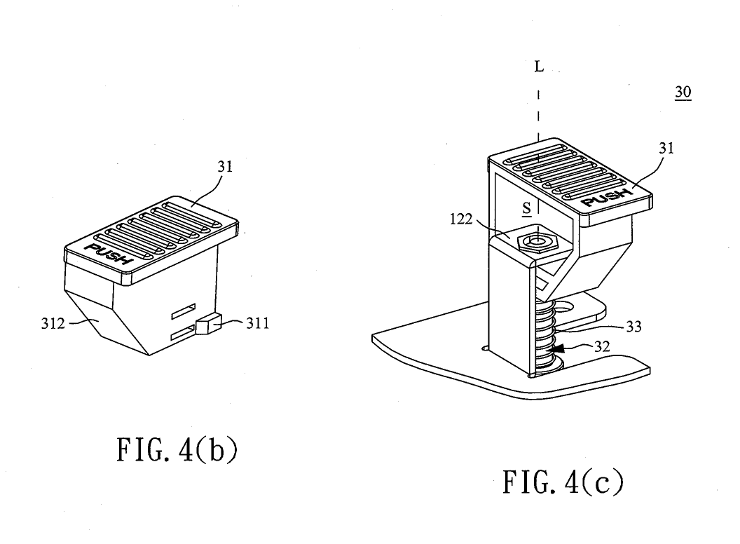

Please refer to FIG. 4(a) to FIG. 4(c). FIG. 4(a) is an exploded diagram of the button unit 30 and the fixing support 12 of the detachable assembly 1. FIG. 4(b) is a structural diagram of a button 31 of the detachable assembly 1 of the electronic apparatus viewed from another angle. FIG. 4(c) is a structural diagram of the button unit 30 combined with the fixing support 12 in the detachable assembly 1 of the electronic apparatus.

As shown in FIG. 4(a) to FIG. 4(c), each button unit 30 includes a button 31, a fixed assembly 32 and an elastic element 33. The button 31 is movably combined with the main frame 10, and the button 31 includes a protruding part 311 and the inclined plane 312. The protruding part 311 is disposed on an outer lateral side of the button 31 for corresponding to the hook part 241 of the actuation part 24 of the tray 20 mentioned in FIG. 3. The protruding part 311 further includes an inclined plane, a curved plane or a round corner structure for moving smoothly with respect to the hook part 241. The inclined plane 312 is also disposed on an outer surface of the button 31 for corresponding to the corresponding inclined plane structure 242 of the actuation part 24 of the tray 20 in FIG. 3. In this embodiment, the button 31 forms a storage space S, and the bending part 122 of the fixing support 12 of the main frame 10 is inserted into the storage space S via a side of the button 31 opposite to the outer lateral surface on which the protruding part 311 is disposed.

The fixed assembly 32 is fixed to the bending part 122 of the fixing support 12 and passes through the first opening 313a of the button surface 313 of the button 31 such that the button 31 moves along the axis L corresponding to the fixed assembly 32. Because the bending part 122 is located in the storage space S, the button 31 can be blocked by the bending part 122 while the button 31 is moving toward the main body 11 along the axis L. The elastic element 33 is sleeved on the fixed assembly 32 for providing an elastic recovery force after the button 31 is pressed by an external force.

In one embodiment of the present disclosure, the fixed assembly 32 includes a fixed post 321, and a spring base 322 is capable of being combined with the fixed post 321. One end of the fixed post 321 is fixed to the bending part 122 and the other end of the fixed post 321 is combined with the spring base 322. A length a of the fixed post 321 is smaller than a length b of the storage space S along the axis L such that when the fixed post 321 is fixed to the bending part 122, the button 31 is capable of being installed on the fixing support 12 and then the fixing column 321 is combined with the spring base 322. However, the present disclosure should not be limited to this.

In addition, a partition 314 button can be disposed in the storage space S of the button 31. The partition 314 includes a second opening 314a corresponding to the first opening 313a, and the second opening 314a and the first opening 313a are both circular holes with the axis L as a central axis. The fixed assembly 32 can pass through the first opening 313a of the button surface 313 of the button 31 and the second opening 314a of the partition 314 such that the button 31 can move steadily along the axis L. However, the present disclosure is not limited to this.

One end of the spring base 322 with respect to the other end, combined with the fixed post 321, is fixed to the main frame 10 or the housing of the electronic apparatus (not shown). The elastic element 33 includes two ends 33a and 33b. The end 33a of the elastic element 33 is contacted the bottom surface 313 of the button 31, and the other end 33b is contacted a cover part 322a of the spring base 322.

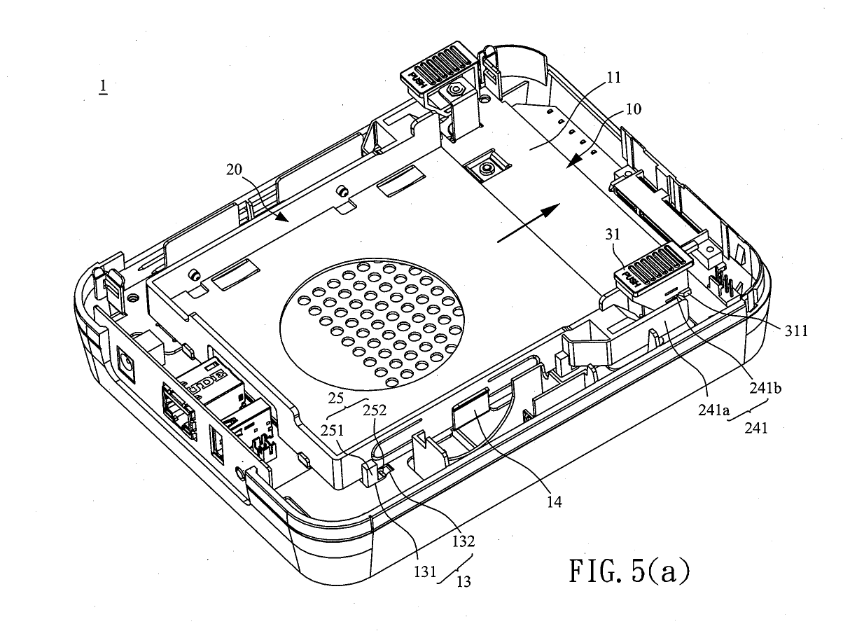

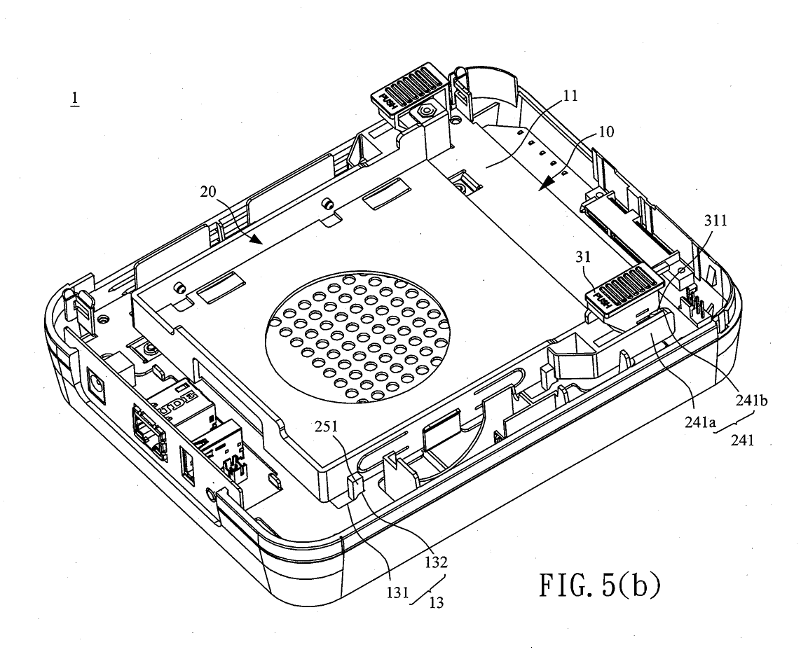

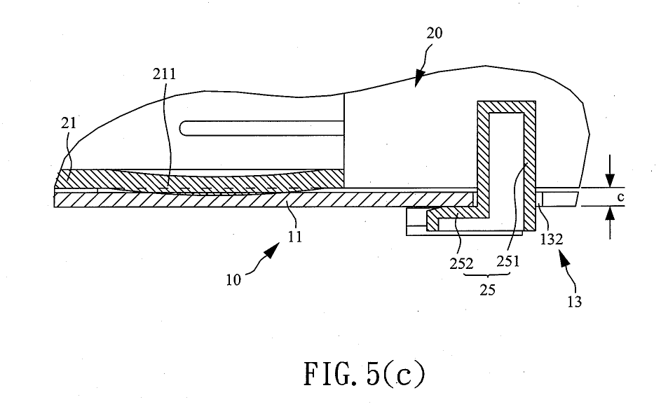

Please refer to FIG. 5(a) to FIG. 5(c). FIG. 5(a) illustrates a combination process of the tray 20 and the main frame 10 in the detachable assembly 1. FIG. 5(b) illustrates the status after the tray 20 is combined with the main frame 10 in the detachable assembly 1. FIG. 5(c) is a sectional diagram of the status after the tray 20 is combined with the main frame 10 in the detachable assembly 1.

As shown in FIG. 1 and FIG. 5(a), when the tray 20 mounted the storage device 80 combines with the main frame 10, the plurality of fasteners parts 25 of the tray 20 are aligned with the plurality of holes 13 of the main frame 10 first; then the tray 20 can be assembled substantially perpendicularly to the main body 11. Each fastener part 25 passes through each through hole 131 completely and preliminarily combines the tray 20 with the main frame 10 as shown in FIG. 5(a). The hook part 241 of the tray 20 does not contact the button 31 yet.

As shown in FIG. 5(a), each hole 13 of the main frame 10 comprises a through hole 131 and an extending hole 132. The through hole 131 is connected to the connecting hole 132 by an inclined plane structure. The connecting part 251 of each fastener part 25 of the tray 20 can only slide along the direction of the arrow illustrated in FIG. 5(a) due to the inclined plane structure. When a user pushes the tray 20 along the direction of the arrow, the connecting part 251 of each fastener part 25 moves into the extending hole 132 of each hole 13, as shown in FIG. 5(b). During the movement of the tray 20 from the position in FIG. 5(a) to that in FIG. 5(b), the hook 241b of the hook part 241 of the tray 20 contacts the protruding part 311 of the button 31 first. Acted upon by the elastic force of the spring arm 241a of the hook part 241, the hook 241b can slide across the protruding part 311 and finally form a locked status with the hook 241b and the protruding part 311, as shown in FIG. 5(b). At this moment, the tray 20 is in a fixed position and cannot move with respect to the main frame 10.

As shown in FIG. 5(b) and FIG. 5(c), when the tray 20 is located in the fixed position, the connecting part 251 of each fastener part 25 is located in the extending hole 312 of each hole 13. At this moment, the tray 20 cannot be detached from the main frame 10 along a direction substantially perpendicular to the main body 11 because the main body 11 of the main frame 10 fixes the extending part 252 of the fastener part 25. Because the plurality of buffer structures 211 protrude outwardly from the bottom plate 21 of the tray 20, the bottom plate 21 of the tray 20 contacts the main frame 10 at multiple points to decrease the contact area and friction between the tray 20 and the main frame 10. The buffer structures 211 also provide buffer and vibration absorbing effects. In addition, in the structure design of one embodiment of the present disclosure, the distance c between the extending part 252 of each fastener 25 and the base board 21 is not smaller than the thickness of the main body 11 and is not larger than the sum of the thickness of the main body 11 and the height of the buffer structure 211 protruding from the bottom plate 21 to facilitate combination of the tray 20 with the main frame 10.

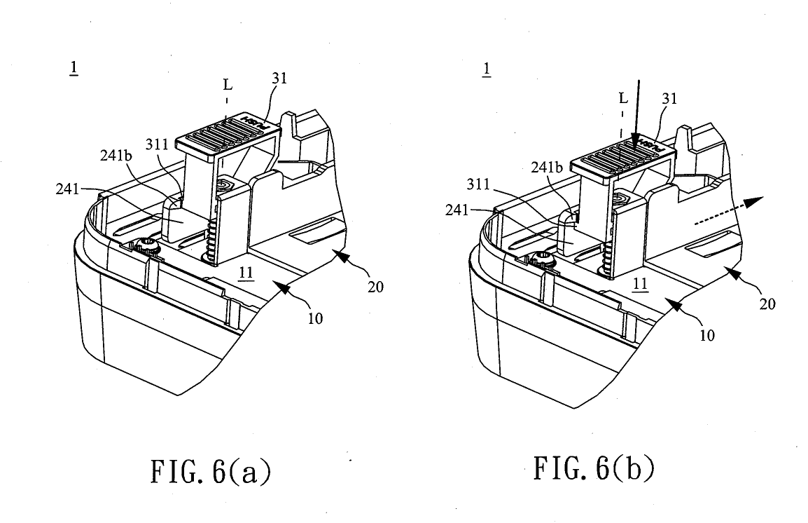

FIG. 6(a) illustrates the locked status of the button 31 and the tray 20 of the detachable assembly 1 of the electronic apparatus. FIG. 6(b) illustrates the release of the locked status of the button 31 and the tray 20 of the detachable assembly 1 of the electronic apparatus when the button 31 is pressed.

As shown in FIG. 6(a), after the tray 20 is combined with the main frame 10, the hook 241b of the hook part 241 of the tray 20 hooks the protruding part 311 of the button 31 such that the tray 20 cannot move in the direction opposite to the direction of the arrow in FIG. 5(b) to keep the tray 20 and the storage device mounted and thereon fixed.

As shown in FIG. 6(b), when the user applies force to press the button 31 in the direction of the arrow in the drawing, the button 31 moves along the axis L substantially perpendicular to the main body 11. At this moment, the protruding part 311 also moves with the button 31 such that the protruding part 311 gradually releases the locked status with the hook 241b. When the button 31 is kept pressed and moved to a certain distance at which the hook 241b is not affected completely by the protruding part 311, the tray 20 can move along the direction of the dashed arrow in the drawing such that the tray 20 is released from the main frame 10.

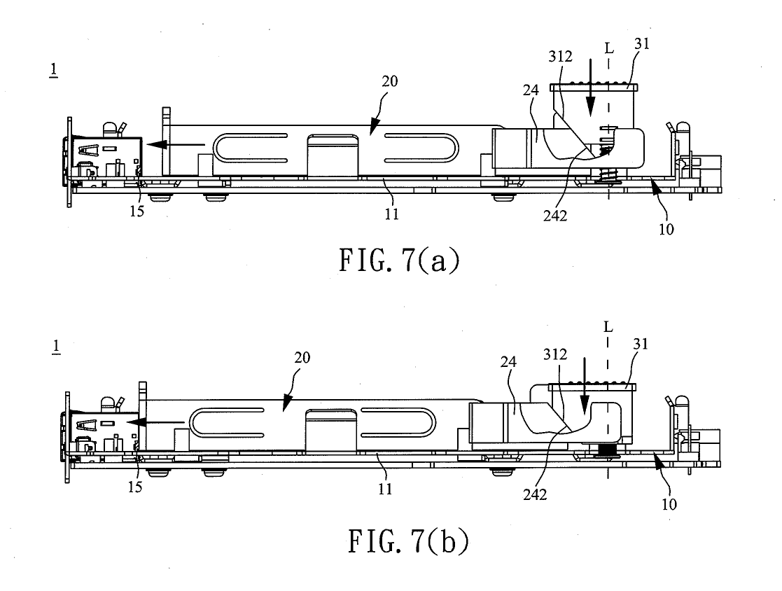

Please refer to FIG. 7(a) to FIG. 7(b). FIG. 7(a) is a side view before the button 31 pushes the tray 20 in the detachable assembly 1 of the electronic apparatus. FIG. 7(b) is a side view after the button 31 pushes the tray 20 in the detachable assembly 1 of the electronic apparatus.

As shown in FIG. 7(a), when the user applies force to press the button 31, the button 31 is released from the locked status from the tray 20 and the inclined plane 312 of the button 31 also gradually contacts the corresponding inclined plane 242 of the actuation part 24 of the tray 20. Because of the interaction between the different inclined planes, the button 31 moves along the axis L substantially perpendicular to the main body 11 and pushes the corresponding inclined plane 242 of the tray 20 because of the inclined plane 312. The tray 20 can move along a plane substantially perpendicular to the axis L; that is, the tray 20 can move along the plane substantially parallel to the main body 11.

Accordingly, the tray 20 moves with respect to the main frame 10 from the position in FIG. 7(a) to that in FIG. 7(b) to leave the fixed position such that the user can easily remove the tray 20 to replace the storage device 80. When the tray 20 is moved from the fixed position in FIG. 7(a) to that in FIG. 7(b), at least one block part 15 can limit the ejection distance of the tray 20 to prevent the tray 20 from contacting other components of the electronic apparatus.

The foregoing descriptions of embodiments of the present disclosure have been presented only for purposes of illustration and description. They are not intended to be exhaustive or to limit the present disclosure to the forms disclosed. Accordingly, many modifications and variations will be apparent to practitioners skilled in the art. Additionally, the above disclosure is not intended to limit the present disclosure. The scope of the present disclosure is defined by the appended claims.

What is claimed is:

1. A detachable assembly of an electronic apparatus, comprising:
a main frame;
a tray for mounting a storage device and being detachably combined with the main frame, the tray comprising a base board and two lateral boards opposite to each other, each of the lateral boards being substantially perpendicularly connected to the base board, and each of the lateral boards extending outwardly to form an actuation part, the actuation part comprising a hook part;
at least one button unit, each of the button units comprising a button movably combined with the main frame, and the button comprising a protruding part corresponding to the hook part;
when the tray is combined with the main frame and located in a fixed position, the protruding part of each button and each hook part of the tray form a locked status;
when each button moves along an axis toward the main frame due to an external force, each protruding part is released from the locked status with each hook part, and the tray is pushed by the button to move along a plane substantially perpendicular to the axis such that the tray leaves the fixed position and is detached from the main frame.

2. The detachable assembly of the electronic apparatus of claim 1, wherein the main frame comprises at least one fixing support for installing the button unit, and each fixing support comprises an erect part and a bending part substantially perpendicular to the erect part.

3. The detachable assembly of the electronic apparatus of claim 2, wherein each button unit further comprises a fixed assembly and an elastic element; the elastic element is sleeved on the fixed assembly and contacts the button, and the button forms a storage space; the bending part is located in the storage space, and the fixed assembly is fixed to the bending part and passes through a first opening of a bottom surface of the button such that the button can be blocked by the bending part when the button is moving along the axis.

4. The detachable assembly of the electronic apparatus of claim 3, wherein the fixed assembly comprises a fixed post and a spring base capable of being combined with the fixed post; a length of the fixed post is smaller than a length of the storage space along the axis, and the elastic element comprises two ends respectively propped to the bottom surface of the button and the spring base.

5. The detachable assembly of the electronic apparatus of claim 4, wherein the button further comprises a partition disposed in the storage space; the partition comprises a second opening corresponding to the first opening, and the fixed assembly passes through the first opening and the second opening to keep the button moving along the axis.

6. The detachable assembly of the electronic apparatus of claim 1, wherein each button further comprises an inclined plane, and each actuation part of the tray further comprises a corresponding inclined plane; when each button is moved along the axis toward the main frame by an external force, the inclined plane of each button pushes the inclined plane of the tray.

7. The detachable assembly of the electronic apparatus of claim 1, wherein each lateral board comprises at least one elastic piece, and each elastic piece has a convex column for fixing the storage device.

8. The detachable assembly of the electronic apparatus of claim 1, wherein the main frame comprises a plurality of holes, and the tray further comprises a plurality of fastener parts corresponding to the plurality of holes; the plurality of fastener parts pass through the plurality of holes when the tray is combined with the main frame; the tray is fastened with the main frame by the plurality of fastener parts when the tray moves to the fixed position.

9. The detachable assembly of the electronic apparatus of claim 8, wherein each of the fastener parts comprises a connecting part and an extending part; the connecting part is connected to the base board or the lateral board, and the extending part is extended from the connecting part and is substantially parallel to the base board; a distance is maintained between the extending part and the base board for fastening to the main frame.

10. The detachable assembly of the electronic apparatus of claim 9, wherein each of the holes comprises a through hole and an extending hole connected to the through hole; the through hole allows the connecting part and the extending part to pass through it, and the extending hole allows only the connecting part to pass through it.

11. An electronic apparatus, comprising:
a housing;
a circuit board disposed in the housing; and
a detachable assembly disposed in the housing, the detachable assembly comprising:
a main frame;
a tray for mounting a storage device and being detachably combined with the main frame, the tray comprising a base board and two lateral boards opposite to each other, each of the lateral boards being substantially perpendicularly connected to the base board, and each of the lateral boards extending outwardly to form an actuation part, the actuation part comprising a hook part;
at least one button unit, each of the button units comprising a button movably combined with the main frame, and the button comprising a protruding part corresponding to the hook part;
when the tray is combined with the main frame and located in the fixed position, the protruding part of each button and each hook part of the tray form a locked status;
when each button is moved along an axis toward the main frame by an external force, each protruding part is released from the locked status with each hook part and the tray is pushed by the button to move along a plane substantially perpendicular to the axis such that the tray leaves the fixed position and is detached from the main frame.

12. The electronic apparatus of claim 11, wherein the main frame comprises at least one fixing support for installing the button unit, and each fixing support comprises an erect part and a bending part substantially perpendicular to the erect part.

13. The electronic apparatus of claim 12, wherein each button unit further comprises a fixed assembly and an elastic part; the elastic element is sleeved on the fixed assembly and propped to the button, and the button forms a storage space; the bending part is located in the storage space, and the fixed assembly is fixed to the bending part and passes through a first opening of a bottom surface of the button such that the button can be blocked by the bending part when the button is moving along the axial direction.

14. The electronic apparatus of claim 13, wherein the fixed assembly comprises a fixed post and a spring base capable of being combined with the fixed post; a length of the fixed post is smaller than a length of the storage space along the axis, and the elastic element comprises two ends respectively propped to the bottom surface of the button and the spring base.

15. The electronic apparatus of claim 14, wherein the button further comprises a partition disposed in the storage space; the partition comprises a second opening corresponding to the first opening, and the fixed assembly passes through the first opening and the second opening to keep the button moving along the axis.

16. The electronic apparatus of claim 11, wherein each button further comprises an inclined plane, and each actuation part of the tray further comprises a corresponding inclined plane; when each button is moved along the axis toward the main frame by an external force, the inclined plane of each button pushes the inclined plane of the tray.

17. The electronic apparatus of claim 11, wherein each lateral board comprises at least one elastic piece, and each elastic piece has a convex column for fixing the storage device.

18. The electronic apparatus of claim 11, wherein the main frame comprises a plurality of holes, and the tray further comprises a plurality of fastener parts corresponding to the plurality of holes; the plurality of fastener parts pass through the plurality of holes when the tray is combined with the main frame; the tray is fastened with the main frame by the plurality of fastener parts when the tray moves to the fixed position.

19. The electronic apparatus of claim 18, wherein each of the fastener parts comprises a connecting part and an extending part; the connecting part is connected to the base board or the lateral board, and the extending part is extended from the connecting part and is substantially parallel to the base board; a distance is kept between the extending part and the base board for fastening to the main frame.

20. The electronic apparatus of claim 19, wherein each of the holes comprises a through hole and an extending hole connected to the through hole; the through hole allows the connecting part and the extending part to pass through it, and the extending hole allows only the connecting part to pass through it.
